(19) United States
(12) Patent Application Publication
(10) Pub. No.: US 2009/0027280 A1
(43) Pub. Date: Jan. 29, 2009

(54) MICRO-SCALE RESONANT DEVICES AND METHODS OF USE

(76) Inventors: John V. Frangioni, Wayland, MA (US); Jonathan Bernstein, Medfield, MA (US); Jonathan J. Rosen, Newton, MA (US); Robert E. Lenkinski, Newton, MA (US)

Correspondence Address: FISH & RICHARDSON PC, P.O. BOX 1022, MINNEAPOLIS, MN, 55440-1022, US

(21) Appl. No.: 11/913,661

(22) PCT Filed: May 5, 2006
(86) PCT No.: PCT/US2006/017516

§ 371 Date: Aug. 29, 2008

Related U.S. Application Data
(60) Provisional application No. 60/678,045, filed on May 5, 2005.

(51) Int. Cl. G01R 29/08; H01Q 1/40; H01Q 1/00

(52) U.S. Cl. 343/703; 343/873; 343/787

(57) ABSTRACT

The invention relates to micro-resonant devices (MRDs) that generate resonance at radio frequencies not present in an animal or human body, or present at low, background levels in the body. These individual, often monolithic devices, can be located in three-dimensional space and tracked anywhere in a target area, e.g., in a human or animal body, or within a cell within a body, using a conventional magnetic resonance imaging (MRI) scanner or other transducers, e.g., radiofrequency transducers. The MRDs generate high sensitivity contrast in conventional clinical MRI scanners, have a diameter of anywhere from a few nanometers to 1000 microns, and can in some embodiments be manufactured using Micro-Electro-Mechanical Systems (MEMS) technology. The devices are optionally coated to isolate them from the environment, and this coating can be a biocompatible coating for medical and biotechnology uses.

### TECHNICAL FIELD

This invention relates to micro- and nano-scale resonant devices that can be induced to emit a signal that can be used in methods of tracking and imaging the location and movement of the devices, and, in some embodiments, the conditions of the environment surrounding the devices, e.g., within a human or animal body or within some specific environment.

### BACKGROUND

Magnetic resonance imaging (MRI) uses the hydrogen atom, i.e., the proton, to generate contrast. In this technique, a strong magnetic field is used to align the proton's axis of precession, then a radiofrequency (RF) pulse is used to probe the concentration of protons by measuring their resonance at the Larmor frequency. In effect, an MRI scanner is a transmitter/receiver for RF signals. Since the precise resonance frequency will also depend on magnetic field, gradients can be used to encode x-, y-, and z-axes, providing proton concentration in 3-D space, i.e., imaging.

As one might imagine, the signal generated by any one proton is exceedingly small, and concentrations of approximately 80 Molar are required to generate a detectable signal. As a result, there is, at present, no known imaging modality capable of tracking and imaging things as small as single cells, e.g., stem or cancer cells, or even small numbers of stem or cancer cells, as they move within a tissue or an animal or human body. For a variety of technical reasons, nuclear medicine (SPECT and PET), computed tomography, conventional MRI, and ultrasound, all have inadequate sensitivity for cell tracking. Indeed, an improvement of seven to nine orders of magnitude over conventional techniques would be required to track single cells at any anatomic location.

### SUMMARY

The invention is based, in part, on the discovery that if one creates a small enough micro-resonant device (MRD) that can receive an excitation signal and generate and transmit an emission signal, then one can track and/or image single cells in an environment, e.g., a tissue or a human or animal body, with a device that is on the order of about 5 to 100 microns in diameter, and is thus invisible, or essentially invisible, to the human eye. In other embodiments, the MRDs can be larger, e.g., up to about 1000 microns or much smaller, down to about 5 nanometers.

In general, the invention features monolithic MRDs that include an antenna component that receives an excitation signal and transmits an emission signal; and a resonator component that receives an excitation signal and generates a corresponding emission signal; and, optionally an outer coating that envelopes the device and isolates the device from its environment. These devices have an overall diameter of less than about 1000 microns, e.g., 100 or 10 microns, and a Q value of greater than about 5, e.g., greater than 10, 50, 100, or much higher, and the emission signal is (i) a resonant frequency of the device emitted at a delayed time compared to the excitation signal (or at a time after the excitation signal has stopped), (ii) a frequency different than the excitation signal; (iii) a signal at a different polarization than the excitation signal, or (iv) a resonant frequency of the device (when the device is tuned to the same frequency as the nuclei being imaged) which upon excitation by an excitation field (e.g., a magnetic field), distorts the applied excitation field.

In these new MRDs, the antenna component and the resonator component can be the same component, i.e., one component that functions as both an antenna and as a resonator. When the coating is present, it can be a biocompatible coating, e.g., a parylene, polyethylene glycol, carbon, sugar, carbohydrate, hydrophilic peptide, amphilic peptide, surfactant, or an amphilic polymer. The coating can be cross-linked, and the carbon can be or include amorphous carbon, diamond, or nano-crystalline diamond. The MRDs can include one or more endocytosis-promoting molecules linked to the coating, such as peptides that include an amino acid sequence RGD, a transferrin molecule, a fibronectin molecule, an low density lipoprotein (LDL) cholesterol molecule, or an apoliprotein B-100 molecule. The coating can also include one or more targeting molecules as described herein.

The MRDs can, in some embodiments, have a resonant frequency that is not present in a subject into which the devices are implanted or a frequency that is present in the subject, but at a low background level. The devices can also be designed such that the resonant frequency is proportional to an applied magnetic field, e.g., by fabricating the resonator of a magnetic metal or alloy to induce magnetic field dependence to the resonant frequency.

In certain embodiments, the invention features MRDs in the form of cylindrical or prismatic length extender bars that include a transducer material, e.g., a piezoelectric or magnetostrictive transducer material, and that have a length of less than about 100 microns and a diameter of less than about 100 microns; and optionally an outer coating that envelopes the device and isolates the device from its environment. These MRDs resonate at a resonant frequency of greater than about 50 MHz after receiving an excitation signal at the resonant frequency.

When these MRDs include the outer coating, it can include an outer layer that includes a hydrophilic material encompassing the device; and an inner layer including a hydrophobic material located between the outer layer and the bar. The MRDs can have a Q value greater than 5, and the transducer material can be zinc oxide, aluminum nitride, a nickel alloy, or a magnetostrictive ferrite containing Fe, Ni, or Co. The magnetostrictive ferrite can be, for example, NiFe₂O₄ or Ni_{0.95}Cu_{0.02}Fe₂O₄. The inner layer can be made of a porous material of low density, or a block-copolymer from which one of the co-polymers has been removed. The resonant frequency can be greater than about 400 MHz, greater than about 2 GHz, or even greater than 1 THz.

In other embodiments, the new MRDs are in the form of devices that include a hermetically-sealed housing having walls forming an internal chamber; a cantilever arranged within the internal chamber and having a free end and a fixed end connected to a wall of the housing; and an electrode arranged within the internal chamber in parallel and spaced from the cantilever; wherein the overall size of the device is no larger than about 1000 microns, e.g., no larger than 100 or 10 microns.

These MRDs can further include a biocompatible coating on an external surface of the housing. The chamber can be substantially free of gas molecules, e.g., the chamber can be under a partial or complete vacuum. The cantilever and the electrode can each be made of silicon (e.g., polysilicon) and the housing can include silicon nitride. The cantilever and electrode can be made of the same material, or different materials, e.g., with different electron work functions. For example, one material of the cantilever or electrode can be silicon doped N and a second material of the electrode or cantilever can be silicon doped P. In certain embodiments, the cantilever can be made of a magnetic metal or alloy to induce magnetic field dependence to the resonant frequency.

In certain other embodiments, the new MRDs are in the form of a sandwich of at least two layers rolled into a cylinder, wherein a first layer includes a conductor and a second layer comprises an insulator; wherein the device has an overall diameter of less than 5 mm and a Q value of greater than 5; and wherein when exposed to an excitation signal at a resonant frequency of the device, the device generates an emission signal comprising the resonant frequency for a time after the excitation signal has ended.

These MRDs can also include a third magnetic layer made of, e.g., iron, nickel, cobalt, or alloys thereof, or other magnetic materials described herein. These MRDs can also include an outer coating that envelopes the device and isolates the device from its environment. This coating can be biocompatible as described herein, and can contain various targeting molecules and other ligands. For example, in some embodiments, the outer coating can include one or more ligands that specifically bind to one or more different target moieties, wherein binding of the ligand to the target moiety induces a change in the frequency of the emission signal. For example, the target moiety can be a calcium ion, carbohydrate, nucleic acid, polypeptide, or chemical.

The invention also features, new MRDs in the form of planar L-C resonator devices that include a spiral inductor and a thin-film capacitor. Alternatively, the new MRDs can be manufactured in the form of piezoelectric cantilever resonator devices having a loop antenna. Further details of these devices are described herein.

In another aspect, the invention features methods of locating or tracking one or more of the MRDs described herein, by generating an excitation signal in a target area in which the device might be located; receiving an emission signal from the one or more MRDs, if any, in the target area; and processing the emission signal to determine the location of the device. In addition, the MRDs can be imaged by processing the emission signal and generating an image from the processed emission signal. In various methods, the MRDs can have an overall diameter of about 10 microns or less, and be located within a cell, to thereby enabling the cell to be located within the area. In embodiments in which the emission signal is a resonant frequency of the MRD, the device can further include a magnetic material to induce magnetic field dependence to the resonant frequency, and the methods can further include exposing the target area to a magnetic field.

In these methods, the target area can be within a subject, such as an animal or human body, and the emission signal can be a frequency of at least 100 MHz, e.g., 400 MHz, 2 GHz, or 1 or more THz. The cell can be a stem cell or cancer cell, and the target area can be a human or animal body. In certain embodiments, the MRDs can be attached to an object, and the methods can be used to track the object within a target area. For example, the object can be a surgical device and the method can be used to track the surgical device in a hospital surgery room. In another example, the MRD can be attached to or carried within a human or animal body, and the method can be used to track the body in a target area, e.g., covertly. The MRDs can include one or more ligands that specifically bind to a target moiety and induce a change in the frequency of the emission signal of the MRD, in which case, the methods can be used to sense a change in the environment of the target area. For example, the change in the environment can be a change in pH, or a change in concentration of an ion, polynucleotide, polypeptide, carbohydrate, or chemical.

A “micro-resonant device” has an overall outer diameter or dimension of less than about 1000 microns, and can be much smaller, e.g., less than 500, 250, 100, 50, 20, 10, 5, or 1 micron, or even on the nanometer scale, e.g., 500, 250, 200, 100, 50, 25, 10, or 5 nanometers. Micro-resonant devices can be individual, standalone, monolithic devices, or can be made of a set of nano-resonant devices that are each on the nanoscale, i.e., about 500 nanometers or less, e.g., less than 250, 100, 50, 25, 10, or 5 nanometers in size.

The nano-resonant devices either (i) individually produce a resonant signal, and when acting in concert in a particular target location, the set of nano-resonant devices produces a collective signal of sufficient power to be detected in the same way that a signal from a micro-resonant device is detected, or (ii) individually do not produce a signal, but assemble, e.g., self-assemble, at a target location to form a micro-resonant device to produce a detectable signal or collectively act like a micro-resonant device to produce a detectable signal. Once congregated or self-assembled at a target location, the set of nano-resonant devices can act like a micro-resonant device. Alternatively, nano-resonant devices can individually produce a detectable signal and serve as a micro-resonant device, depending on their size and resonant frequency.

A micro-resonant device about 10 microns or less in overall diameter can be delivered into a cell, e.g., by endocytosis. A nano-resonant device that is about 5 nanometers or less in overall diameter can pass through the endothelial walls of blood vessels and can thus pass into tissue cells outside the vasculature.

The invention provides various advantages. The new MRDs are passive, biocompatible, robust, solid-state devices, that are small enough to be engulfed by cells, such as stem cells, via endocytosis, and are designed to reside harmlessly in the cytoplasm. Thus, the new MRDs can be used to track single cells as they traverse the body. The new MRDs are also designed to emit frequencies that are not normally present in the body (or the particular target environment), or are at such a low, background level in the environment compared to the signal from the MRD, so that the MRDs are easily discernable using a variety of detection systems. The new MRDs can also be designed to have a sufficiently high Q that they can be used with standard MRI systems.

The MRDs can be designed and fabricated so that their resonant frequency is sensitive to their surrounding temperature, chemistry, pH, or specific target moieties, such as specific nucleic acids, ions, polypeptides, carbohydrates, or chemicals, thus making them useful as local sensors with an RF readout. In addition, MRDs composed of metallic layers can be detected by conventional computed tomography (CT), thus adding another dimension to their usefulness as contrast agents.

Beyond medicine, because of their microscopic size MRDs have the potential to act as “invisible” RF tags, being used to track individuals during covert operations, mission-critical equipment, and removable storage devices in secure locations. In another embodiment, due to their extremely small size, thousands or millions of these MRDs can be placed on an object to be tracked, which could slowly shed the MRDs to form a “trail” allowing the object to be tracked.

In all embodiments, because the new MRD devices are passive, they cannot be detected unless stimulated by the proper excitation frequency. Furthermore, in various embodiments, their emission signals can be modulated by their environment.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

Other features and advantages of the invention will be apparent from the following detailed description, and from the claims.

### DESCRIPTION OF DRAWINGS

FIGS. 1A and 1B are schematic diagrams illustrating a family of MRDs: FIG. 1A shows a Type I MRD, which functions analogously to NMR-active atoms, emitting a characteristic resonant frequency equivalent to the excitation frequency. FIG. 1B shows a Type II MRD, which functions analogously to an optical fluorescent particle, converting an input excitation frequency and/or polarization into a different and discrete emission frequency and/or polarization.

FIG. 1C is an equivalent circuit diagram for a generic micro-electro-mechanical system (NEMS) MRD with antenna input. This circuit is linear (does not generate harmonics) and thus represents a Type I MRD with an electrical input and output.

FIG. 2 is schematic of a cantilever flexural resonator constructed using MEMS technology and hermetically sealed. This MRD can be operated as a Type I or Type II MRD device.

FIGS. 3A to 3J are a series of schematic illustrations of various steps in a process for making a cantilever flexural resonator of FIG. 2 in which the cantilever and electrode are made of the same material.

FIG. 3K is a schematic illustration of a cantilever flexural resonator of FIG. 2 in which the cantilever and electrode are made of different materials.

FIG. 4A is a schematic of a Type I MRD length extender bar made of piezo or magnetostrictive material.

FIG. 4B is a schematic of a cross-sectional view cut along the longitudinal axis of the device in FIG. 4A.

FIG. 5 is a graph showing the resonant frequencies versus length for various materials: Ni, AlN, and ZnO for the length expander bar of FIGS. 4A and 4B.

FIGS. 6A and 6B are schematic diagrams of a Swiss-Roll Type I MRD. FIG. 6A shows a perspective view and FIG. 6B shows a cross-section cut perpendicularly through the longitudinal axis of the device of FIG. 6A.

FIGS. 6C to 6G are a series of schematic diagrams showing various steps in a process for making a Swiss-Roll Type I MRD of FIGS. 6A and 6B. FIG. 6E is a side view of FIG. 6C. FIG. 6G is a side-view of FIG. 6D, but after the Swiss-Roll has been released from the substrate, but for an anchor.

FIG. 7 is a resonance curve of a 4 mm diameter, 15-turn, Q=3,875 Swiss-Roll as shown in FIGS. 6A and 6B.

FIG. 8A is a schematic diagram of a piezoelectric cantilever resonator MRD with a loop antenna.

FIG. 8B is a schematic cross-section of the piezoelectric cantilever resonator MRD of FIG. 8A taken along line A-A′.

FIG. 9A is a schematic diagram of a planar LC-resonator MRD.

FIGS. 9B to 9G are schematic cross-sections of the planar LC-resonator MRD of FIG. 9A taken along line A-A′.

FIG. 10 is a representation of a photomicrograph of a planar LC-resonator MRD with a 250 micron diameter coil.

FIG. 11 is a representation of a scanning electron microscope image of a planar LC-resonator MRD with a 0.5 mm coil.

Like reference symbols in the various drawings indicate like elements.

### DETAILED DESCRIPTION

### Micro-Resonant Devices

The new MRDs are micron-sized, solid-state devices that can generate and emit signals at resonant frequencies not present (or at very low levels) in the target environment, e.g., a human or animal body, and thus provide high sensitivity contrast. These individual devices, e.g., located in a target environment, such as within a single cell, can be located in three-dimensional space and tracked anywhere in the target environment using conventional magnetic resonance imaging (MRI) scanners or radio frequency (RF) transducer/emitters. For example, at 3T, the Larmor frequencies of hydrogen (H-1) and fluorine (F-19) are 127.74 MHz and 120.15 MHz, respectively. Hence, an MRD with a resonant frequency below 127.74 MHz (the highest detectable frequency of a standard clinical scanner), and not at any known Larmor frequency in the body, will provide high signal with extremely low background. If an RF device is used, one or more can be used to locate the presence of the MRDs and can also determine the 3-D location, e.g., by using three separate RF devices. Alternatively, one can use even a single antenna (RF device) if it were focused (or shielded to a small sensitive area) and rotated around the target.

In general, the MRDs have an overall diameter of less than about 1000 microns, e.g., 500, 250, 100, 50, 25, 15, 10, 5, or 1 micron, and can be manufactured using micro-electro-mechanical system (MEMS) technology. In certain embodiments, the MRDs can be even smaller, e.g., on the nano-scale, and can be 500, 250, 100, 50, 20, 10, or even 5 nanometers in overall size or diameter. The overall diameter is the largest size, e.g., length, width, or height, of a device. The new MRDs under about 100 microns in size are inherently invisible to the human eye, but enable the detection, imaging, and tracking of objects, e.g., cells, instruments, and/or people or animals, that contain or carry one or more MRDs.

In many embodiments, the new MRDs are monolithic devices, i.e., they are fabricated entirely on a single silicon chip or substrate, e.g., using MEMs technology. They are also standalone devices, in that they operate without the need for any connection to another circuit or device. Their only power requirements are provided from the detectors used to track and image the MRDs. The new MRDs can be detected individually, or when they are composed of a set of nano-scale MRDs, they can be detected when congregated at a target location within a target environment or area.

In certain embodiments, the new MRDs have a coating that insulates them from the environment. For example, the coating can be hermetically sealed to keep the interior of the MRD free from fluids, e.g., liquids and/or gases in the environment, such as water, organic or inorganic solvents, bodily fluids, air, oxygen, and nitrogen. The coating allows the new MRDs to operate without interference from the environment, and thus have a high Q value. For use in biological or medical settings, this coating is typically a biocompatible coating, such as a polymer like polyethylene glycol. The coating can also include targeting moieties, that enable the MRDs to target or “home” to a particular location in the target environment, e.g., a specific tissue or cell type in a human or animal body. The targeting moieties can also be selected to enhance endocytosis of the MRDs.

MRDs can be designed to operate in one of two modes, one analogous to protons in conventional NMR (thus, the new MRDs can serve as “artificial protons”), and the other analogous to optical fluorescence (described in more detail below). We refer to these two modes herein as “Type I” and “Type II” MRDs. Both Type I and Type II MRDs must have at least the following characteristics: (i) have a Q resonance value of at least 5, e.g., at least 10, 25, 50, 100, 250, 500, or more (in some embodiments, it is important for the Q value to be high, i.e., greater than about 100, e.g., 250, 500, 1000, 3000, 5000, or even 10,000 or more); (ii) emit a signal that is either at a delayed time, at a different frequency, or has a different polarization than the input signal so that it can be detected; and (iii) be small enough for the intended purpose (e.g., for cell-based medical applications, ≦10 μm in overall diameter). Type I MRDs must also emit a resonant frequency that is proportional to the applied magnetic field, if they are to be used with a clinical MRI scanner for 3-D localization. Type II MRDs can be used with any detection system, and does not require an MRI scanner, because their emission signal is not dependent on an applied magnetic field.

In certain embodiments, the Type I MRDs can be tuned to the same frequency as the nuclei being imaged, and can then be imaged based on the contrast they create by distorting the excitation field in their vicinity. For example, an MRD tuned to resonate at 127.74 MHz (in a 3T excitation field) can be detected by standard clinical MRI of protons by the distortion in the field, which has the appearance in a spin-echo MRI image of ripples from a pebble dropped in a pond. Similarly, the MRDs can be tuned to resonate at frequencies of other nuclei, e.g., 119.5 MHz for fluorine, 33.8 MHz for sodium, 51.7 MHz for phosphorous, and 31.9 MHz for carbon. In these embodiments, a Q of about 50 or higher is sufficient to create a visible distortion pattern.

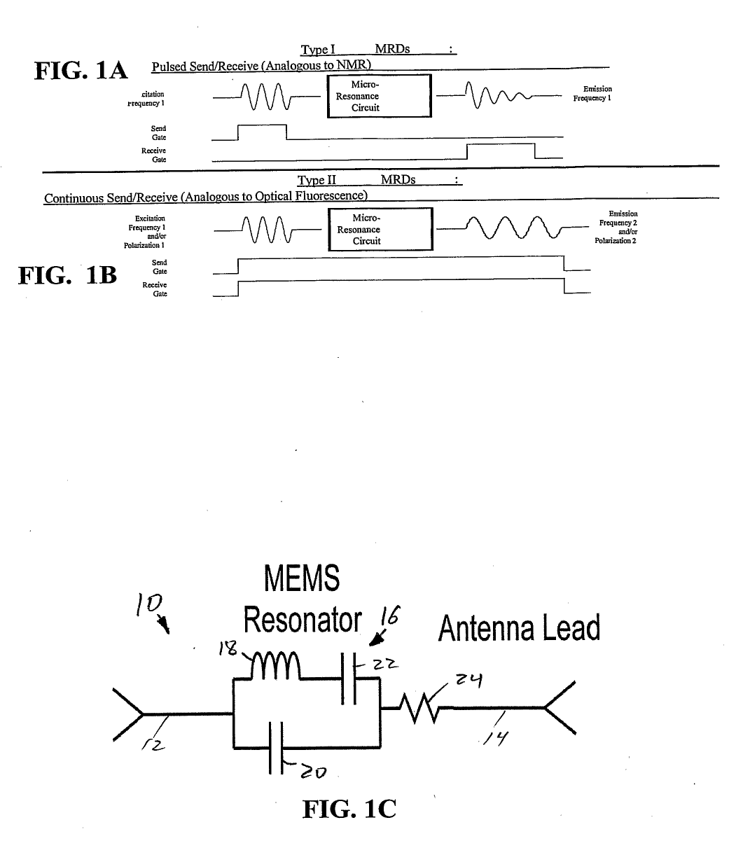

FIG. 1A provides a schematic illustration of a Type I MRD, which functions like a proton and other MR-active atoms, emitting a characteristic resonant frequency in response to an excitation pulse. Thus, a “send gate” is turned on to produce the RF excitation pulse, and is then turned off. Thereafter, a “receive gate” is turned on to read the RF emission signal. In this embodiment, the excitation and emission frequencies can be the same, or essentially the same. Type I MRDs can include a thin layer of a magnetic metal, such as Fe, Ni, Co, or a magnetic alloy, such as alloys made of these metals, to serve as a magnetic field sensitive element to enable magnetic field gradients in an MRI scanner to modulate the resonant frequency of the MRDs. This, in turn, permits precise 3-D localization of each MRD in vivo using MRI. This magnetic field sensitive element is required only if localization in a conventional MRI is desired.

FIG. 1B illustrates a Type II MRD, which functions analogously to an optical fluorophore, that is, an excitation frequency and/or polarization is converted by the MRD into a distinct and different emission frequency and/or polarization. In particular, an optical fluorophore “absorbs” light of one wavelength (i.e., frequency) and emits light at a specific longer emission wavelength, i.e., lower energy. The peak absorbance and emission is fixed by the chemical structure of the fluorophore. In this embodiment, the excitation and emission frequencies are typically different, or at least the polarization of the two signals is different. As shown in FIG. 1B, the significant advantage of Type II MRDs is that excitation and emission are continuous (i.e., the “send gate” and “receive gate” can both be on simultaneously, although this advantage is offset by added complexity of the device. The non-linear effects in a type II MRD can double the input frequency, producing an output frequency twice as high as the input, or it can produce sum and difference frequencies from two input frequencies.

FIG. 1C shows an equivalent electronic circuit 10 for a generic Type I MRD coupled to an external field by a pair of electrodes 12, 14 that act as an antenna. The MRD includes a resonator 16, e.g., a MEMS resonator as will be described in further detail below, made up of an inductor 18 and two capacitors 20, 22. One electrode 14 includes a resistor 24, which represents the mechanical and electrical losses in the device. This circuit is very general and can represent any linear device with a single resonance.

In some embodiments, it may be desirable to have the MRDs temporarily or permanently anchored to a substrate for testing purposes, or to form an array of MRDs as part of an RF tag.

The new MRDs can be embodied in various devices, including, for example, a cantilever resonator device, a length extending bar device, and a so-called “Swiss roll” device. These devices will now be described in detail.

Cantilever Flexural Resonator Device

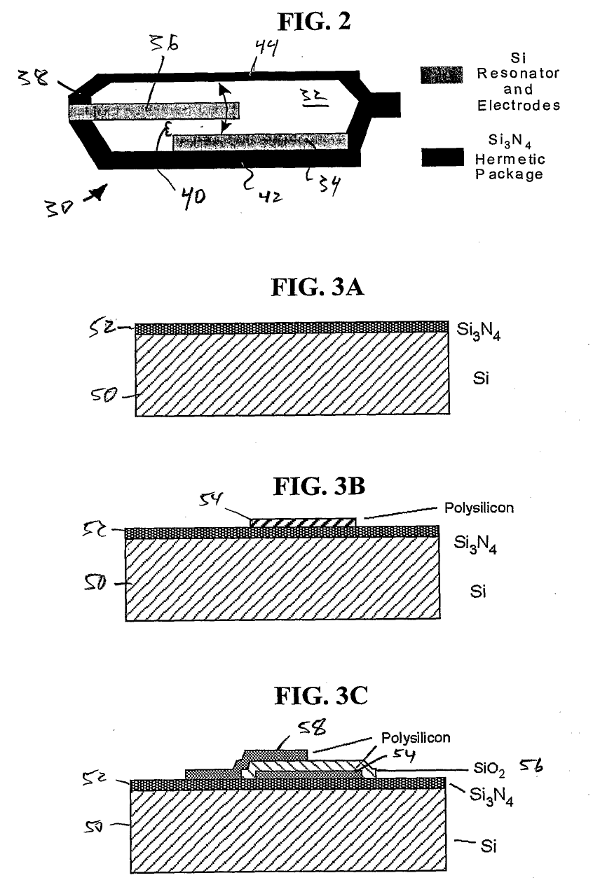

The new MRDs (both Types I and II) can be embodied as a cantilever flexural resonator, and these resonators can be made using standard MEMS methods. In general, as shown in FIG. 2, these MRDs 30 include a hermetically sealed chamber 32 that contains an electrode 34 and a cantilever 36 attached at one end to a side wall 38 of the chamber. In these devices, the cantilever 36 acts as a resonator, and the combination of the cantilever and the electrode, with the gap 40 between them, serves as an antenna. The electrode 34 can be located along a bottom 42 or top 44 wall of the chamber and can be arranged in parallel with the cantilever. The chamber can be made of, for example, Si₃N₄, SiC, SiO₂, Ta₂O₅, diamond, diamond-like carbon, or any other inert and impermeable insulating solid, whilst the electrode and cantilever can be made of doped Si, SiC, or metals such as Pt, Au, Al, Ti, and Ta. The cantilever may contain layers of piezoelectrics such as AlN or ZnO or the magnetostrictive materials noted herein.

The resonant frequency of a cantilever beam is given by:

$$f := \frac{{λ}_{11}^{2}}{2 \cdot π \cdot {a}^{2}} \cdot \sqrt{\frac{{E}_{Si} \cdot {h}^{3}}{12 \cdot γ \cdot ( 1 - {v}_{Si}^{2} )}}$$

where:
λ₁₁ is a constant which is a function of the length/width ratio of the cantilever
a is the length of the cantilever
h is the thickness of the cantilever
γ is the mass/unit area of the cantilever
v_{Si} is the Poisson ratio of the cantilever material, e.g., for silicon the Poisson ratio is between 0.22 and 0.278.
E_{Si} is the Young's modulus of the cantilever material

These parameters are used to design an MRD that has the proper resonant frequency for a desired application. For example, for a silicon cantilever 3.5 microns long and 1 micron thick, the resonant frequency is 114 MHz, which is within the usable frequency range for sensing with a conventional NMR machine. Cantilevers can also be fabricated on the nanometer scale, e.g., 10, 20, 50, 100, 250, or 500 nanometers in length.

The cantilever resonator MRD has the advantage that by adjusting the thickness of the cantilever, the fundamental resonant frequency can be kept in the desired range, even as the length is decreased. Note that the cantilever beam can contain layers of piezoelectric, magnetostrictive, or electret elements, which aid in the transduction. Magnetostrictive materials include Fe, Ni, Co, the rare earth elements, and their alloys, and ferrites such as NiFe₂O₄ and Ni_{0.98}Cu_{0.02}Fe₂O₄ Piezoelectric materials include quartz (SiO₂), AlN, ZnO, PZT (lead zirconate titanate) and barium titanate (BaTiO₃). Electret materials include Al₂O₃, SiO₂, various Teflons® (FEP, PTFE), polyethylene terephthalate (PET), and other electret materials known in the art.

In addition, the inclusion of a magnetic metal layer, such as Fe, Ni, and Co, or a magnetic alloy layer, whose length or mechanical properties (such as strain) change with a magnetic bias field, will result in a resonant frequency that varies with B, and like real protons, can be localized in space based on that variation. Such magnetic materials include the magnetostrictive materials listed above as well as NiFe₂O₄ and Ni_{0.98}Co_{0.02}Fe₂O₄, Fe—Al alloys including AlFer (Fe_{0.87}Al_{0.13}), Terfenol (TbFe₂), and Terfenol-D (Tb_{0.3}Dy_{0.7}Fe₂).

The electrostatically actuated cantilever MRD can be thought of as an interrupted dipole antenna, with a capacitive gap between the two conductive layers. The incident RF field creates an electric field between the cantilever and the second conductor/electrode. The cantilever “sees” square law actuation (force from an E field is proportional to E²), hence the device can be driven at half the resonant frequency, or using sum and difference frequencies that sum or differ by the cantilever resonance. This crucial and unique property means that the device can be constructed to operate as a Type I or Type II MRD, the latter resulting in a very high signal to background ratio.

The cantilever MRD can also be manufactured to include multiple layers of a piezoelectric and or ferromagnetic material to add functionality to the device.

Although any cantilever design is subject to thermoelastic damping (TED), this is not a significant problem in the present MRDs, because TED does not reduce the Q below a few thousand, and this is high enough to operate the device either as a Type I or Type II MRD. In addition, by proper choice of cantilever material, thickness and operating frequency, the effects of thermoelastic damping can be reduced. As is well known, TED can be minimized by selecting a resonant frequency which is far from the inverse of the thermal conduction time constant of the cantilever. An important aspect of the new cantilever MRDs is to attain a vacuum and a sufficiently high Q at a very small size. This can be achieved by sealing the devices hermetically, preferably in a vacuum, or under low or very low pressure gas. In general, the fewer gas molecules are inside the chamber, the better.

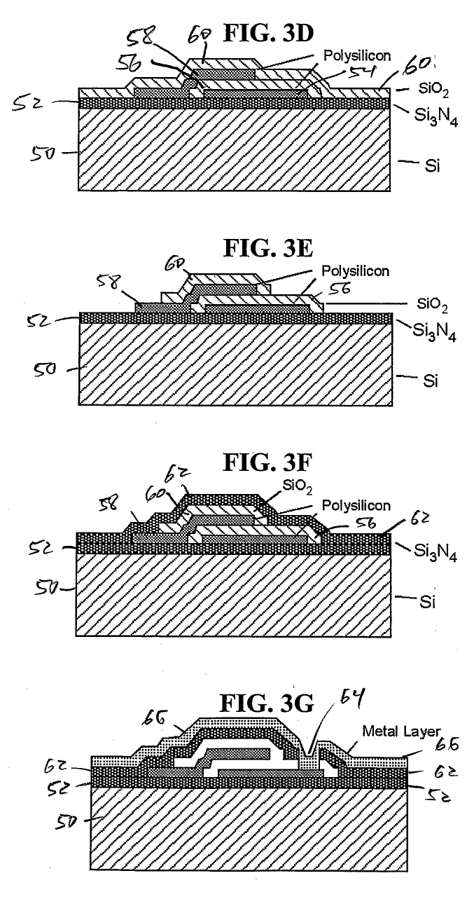

An MRD as shown in FIG. 2 can be fabricated using standard MEMS technology. For example, as illustrated in FIGS. 3A to 3J, the following basic steps can be used for fabricating this device.

As shown in FIG. 3A, a bottom layer 52, such as of Si₃N₄, diamond, diamond-like carbon, SiO₂, or Ta₂O₅ is deposited onto a substrate 50, such as a silicon wafer. The bottom layer can be deposited using standard techniques such as chemical vapor deposition, reactive sputtering, plasma-enhanced chemical vapor deposition, or evaporation. Optionally, a trench (not shown) can be etched into the silicon wafer to receive the bottom layer. Such a trench can be etched using standard techniques, such as chemical and laser etching.

As shown in FIG. 3B, an electrode layer 54, e.g., of polysilicon, is deposited onto the bottom layer 52. The precise size, pattern, and location of the electrode can be established using, for example, photolithographic techniques. This electrode layer 54 can also be doped with, e.g., boron or phosphorus, to increase the electrical conductivity.

As shown in FIG. 3C, the next step is to deposit and pattern a first sacrificial layer 56 of an oxide, e.g., SiO₂, to completely cover the electrode. Many other sacrificial materials are known in the art, such as photoresist, polyimides, and metals such as copper, which can be selectively etched away. Optionally, one can deposit and pattern a piezoelectric or magnetic layer (not shown), which would have the same shape as the upper electrode layer (also referred to as the cantilever). In effect, once the cantilever layer 58 (e.g., polysilicon) is deposited and patterned in the next step (also shown in FIG. 3C), one would have a multi-layer cantilever. The cantilever layer 58 is separated from the electrode 54 by the sacrificial layer 56 and overlaps part of the electrode.

Optionally, one can deposit and pattern another piezoelectric or magnetic layer on top of the cantilever, to produce a two or three-layer cantilever (not shown). By adding a piezoelectric or magnetostrictive layer, the resulting device has additional functionality and can be used in transduction methods. For example, a magnetostrictive layer that expands in a magnetic field would change the radius of curvature of the cantilever and affect its resonant frequency. By adding a piezoelectric layer to the cantilever, a voltage proportional to the mechanical motion is created, giving a linear output at the resonant frequency. For example, inputs at 50 MHz and 60 MHz could be combined through the square law electrostatic actuation to result in a cantilever motion at the resonant frequency of 110 MHz. This motion at 110 MHz then causes the piezoelectric layer to emit a signal at 110 MHz, which can be detected with high resolution due to the lack of drive signals at that frequency.

A still further embodiment of the invention is to include an electret material such as Al₂O₃, SiO₂, or a Teflon® polymer facing the gap between the electrode and the bottom of the cantilever, which would create an electric field, resulting in linear transduction of motion into an electrical output signal. The electret layer can be charged by an electron beam during fabrication or after the micro-chambers are sealed.

In all of these embodiments, the DC field from a work function difference, or an electret, can be useful to create a measurable or enhanced output signal.

After the one or multiple layers of the cantilever 58 are deposited and patterned, a second sacrificial layer 60 is deposited to completely cover the cantilever, the first sacrificial layer 56, and any remaining exposed surface of the bottom layer 52 (FIG. 3D). FIG. 3E shows the result of the next step, in which much of the second sacrificial layer 60 has been removed, e.g., etched away using a timed etch. Alternatively, only those portions of the second sacrificial layer shown in FIG. 3E can be deposited in the first place, thus avoiding the need to remove a portion of this layer.

In the next step, shown in FIG. 3F, an upper layer 62, e.g., of Si₃N₄, is deposited to complete the outer shell or housing that now surrounds an internal chamber in which the cantilever and electrode are located. At this stage, the first 56 and second sacrificial layers 60 (or portions thereof) are still present within the chamber.

FIG. 3G shows the device after a small hole 64 is made to enable the two sacrificial layers to be removed, e.g., by etching with a liquid or vapor acid, such as HF. The entire surface is then vacuum sealed, e.g., with Si₃N₄ LPCVD (Low-Pressure Chemical Vapor Deposition) or by metal evaporation or sputtering to form a surface metal layer 66. This surface metal layer is photolithographically patterned to form a metal plug 68 as shown in FIG. 3H.

As shown in FIG. 3I, plasma etching is used at the circumference of the device to remove excess material layers. The device 30 is then essentially complete, and is removed, e.g., by etching, from the substrate, for example by using XeF₂ or tetramethyl ammonium hydroxide (TMAH). FIG. 3J shows the finished device. Note that the substrate itself could be a sacrificial layer.

A further embodiment of the MRD transduction is the inclusion of a cantilever and bottom electrodes made of two different materials with substantially different electronic work functions. This causes an electric field to be present in the gap between the electrodes given by the work function difference divided by the size of the gap. This arrangement can be used to convert mechanical motion into an electrical signal, and vice-versa, and thus produce a signal linear with the cantilever motion similar to the piezoelectric device described above. Note that semiconductor layers doped N vs. P qualify as different materials from this perspective since they have different work functions. For example, polysilicon electrodes heavily doped N-type and P-type with, for example, phosphorus and boron, will have up to a 1.1 V potential difference (approximately equal to the bandgap of the silicon).

FIG. 3K shows an example of a cantilever MRD with a cantilever and a base electrode made of different materials having different work functions. Slightly different values of the work function can be found in different references (see, e.g., American Institute of Physics Handbook, 3rd ed., pp. 9-172 to 9-178, McGraw Hill 1972) or determined by different methods of measurement, however the precise values are not important. Selecting a pair of metals with a large work function difference such as Ta (which has a work function of about 4 eV) and Os (which has a work function of almost 6 eV), or Al (4.25 eV) and Ni (5 eV) will result in a fairly large electric field across the gap. For example, selecting Al and Ni as electrodes, and a gap of 50 nm, gives an electric field of approximately (5.0−4.25)V/50 nm=1.5×10⁷ V/m, a sizable and useful electric field. A similarly large work function difference would be obtained by doping two silicon layers as N and P type layers.

Piezoelectric or Magnetostrictive Length Extender Bar Design

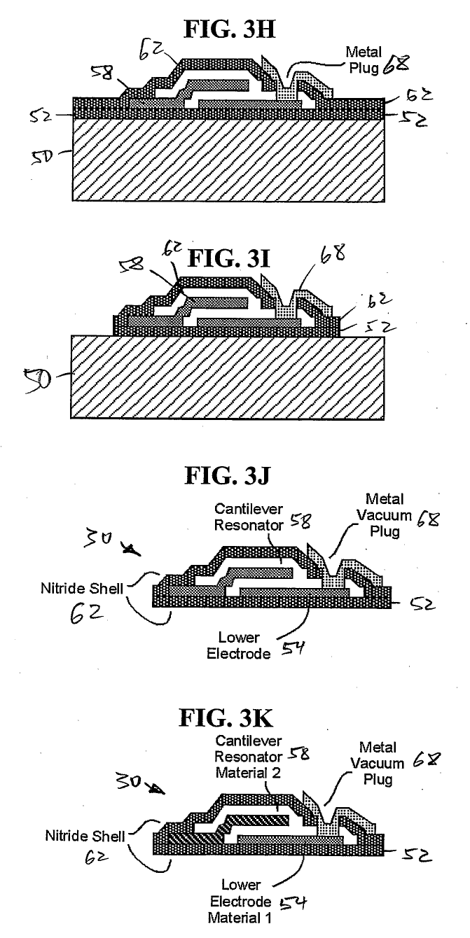

A piezoelectric or magnetostrictive length extender bar MRD is a simple device 70 as shown in FIG. 4A with a length L and diameter D. In these devices, the bar or rod can be a solid or hollow cylinder or prism, and can have a cross-section that is circular, square, hexagonal, or any other shape, depending on the piezoelectric or magnetostrictive transducer material. In addition, in these devices, the bar serves as both a resonator and as an antenna. The size of these MRDs is limited by the speed of sound of available transducer materials. Any of the magnetostrictive materials disclosed herein can be used, as well as piezoelectric materials described herein, such as quartz, barium titanate, polyvinylidene fluoride (PVDF), lead zirconate titanate (PZT), zinc oxide, and aluminum nitride, or alloys of these materials.

The new length extender bar MRDs can be made using various methods of fabrication, depending on the nature of the materials from which they are made. For example, many materials such as ZnO can be grown directly in nano-“whisker” or nanotube form using standard techniques. Any material that can be prepared in thin film form by sputtering or evaporation can be patterned by photolithography into thin bars or needles of a desired length, and then freed from the substrate by undercutting or etching the substrate or a sacrificial layer under the desired bars using standard techniques.

In general, these MRDs can be about 5 nanometers to about 100 microns in length, e.g., 5, 10, 50, 100, 250, or 500 nanometers, or 10, 15, 20, 30, 40, 50, or 100 microns, depending on the specific desired resonant frequency. The formula relating length to resonant frequency is given below. For example, a length extender bar MRD of about 1 micron, with a diameter of about 50 nm would have a resonant frequency in the range of 2 to 3 Gigahertz (GHz). Other MRDs described herein may also be useful in these GHz frequency ranges

Smaller length extender bar MRDs, having lengths on the nanometer scale, can have resonant frequencies in the Terahertz (THz) range, making them useful as contrast agents for Terahertz imaging. This spectral range, e.g., about 100 GHz to about 30 THz, has been accessed in recent times using ultra-fast-laser based terahertz systems. Such a source can be used for high resolution remote subsurface imaging, with spatial and depth resolution better than 1 mm, enabling differentiation of mines from other similar size objects, and is therefore a candidate to augment ground penetrating radar as a means of mine detection. Also, the spectral information of the transmitted and/or scattered radiation could be used to identify materials such as plastics or explosives. Other MRDs described herein can also be useful in these THz frequency ranges.

Smaller length extender bar MRDs can be fabricated by using resonance modes with lower frequency or smaller size (such as bending modes). For example, the fundamental resonant frequency of a thin rod of length L with free-free boundary conditions is given by: f₀=c/2 L, where c is the speed of sound in the rod. Given the speed of sound which is constant for the material, a desired low frequency sets a certain length, as elucidated by the formula above. In contrast, the fundamental resonant frequency of a cantilevered rod (free-fixed boundary conditions) is:

$${f}_{flex} = \frac{1.4 π ct}{16 \sqrt{3} {L}^{2}} .$$

where c is the speed of sound in the material, t is the thickness of the rod perpendicular to the plane of bending, and L is the length. Note that whereas the longitudinal resonant frequency depends only on length, the flexural resonance depends also on thickness, so that it is possible to decrease the size of the resonator by making it thinner. This is true in general for higher order modes and also for other boundary conditions.

Various designs of length extender MRDs include length extender bar piezoelectric resonators, monomorph piezo resonators, and flexural plate wave resonators.

As shown in FIG. 4B, the length extender bar MRD 70 can have a coating 72 that insulates or isolates the device from its environment. In some embodiments, the coating includes an outer hydrophilic layer 72a, and an inner hydrophobic layer 72b, that envelops the piezoelectric or magnetostrictive bar 74. The inner hydrophobic layer 72b can be porous to achieve acoustic decoupling of the resonating bar from the environment, e.g., the surrounding liquid or gas, however, both porous and nonporous layers can be used. The inner hydrophobic layer creates a dry, low acoustic density region that isolates the MRD from its environment and increases the mechanical Q of the resonator. The outer hydrophillic layer 72a ensures that the MRDs can be dispersed in an aqueous environment, such as water or blood, without clumping.

Examples of useful coating materials include hydrophobic poly(methyl methacrylate) (PMMA) and hydrophilic sulphonated polystyrene. Other hydrophilic coatings include hyaluronan (BioCoat, Inc.) and biocompatible hydrophilic hydrogels such as 2-hydroxyl-ethyl-methacrylate (HEMA). Many dendritic polymers can be used as either hydrophilic or hydrophobic layers, depending on their components. See, e.g., Cho et al., “Synthesis and Self Assembly of Amphiphilic Dendrimers Based on Aliphatic Polyether-Type Dendritic Cores,” Macromolecules, 37:4227-4234 (2004). Other examples of useful materials include hydrophobic docosyl outer layers and hydrophilic layer of poly(ethylene oxide). Other hydrophobic layers are polystyrene, polyisoprene, and polyethylene.

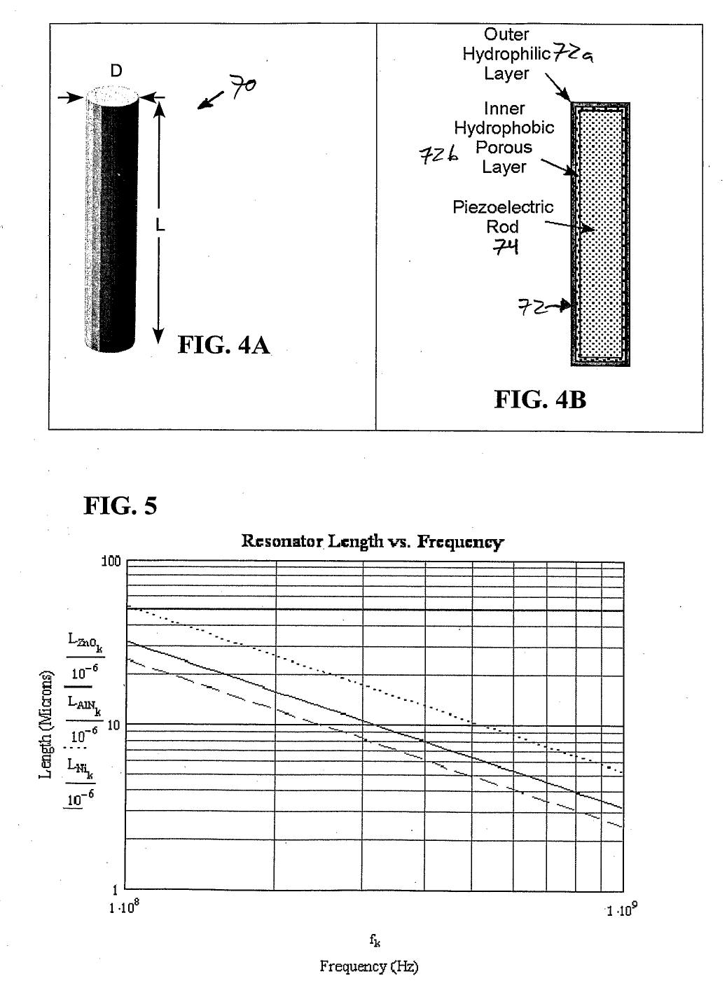

Models of the new length extender bar MRDs have been designed. FIG. 5 is a plot of resonator frequency vs. length for a simple length expander bar, for three different materials. The formula relating length to resonant frequency is given above. In particular, FIG. 5 shows the resonant frequency versus length for length extender bar MRDs. As shown in the graph, resonators made of ZnO, AlN, or Ni alloy that resonate at 100 MHz will have a length of about 23 to 51 microns. If the frequency range is increased to 400 MHz, the length extender bar MRD will be on the order of 6 to 12 microns. In another example, to achieve a 200 MHz resonance, the resonator length is about 16 μm (ZnO) (solid line in FIG. 5) or 12 μm (Ni alloy) (dashed line). AlN (dotted line) has a very high speed of sound, so the resonator length is somewhat larger than for Ni or ZnO.

Swiss-Roll Design

In the Swiss-Roll type resonator, a conductive sheet is rolled into a spiral shape. An insulating layer produces a high capacitance between adjacent layers of the coil, and prevents the adjacent coil turns from short-circuiting to each other. In this design, the coil serves as both an antenna and as a resonator.

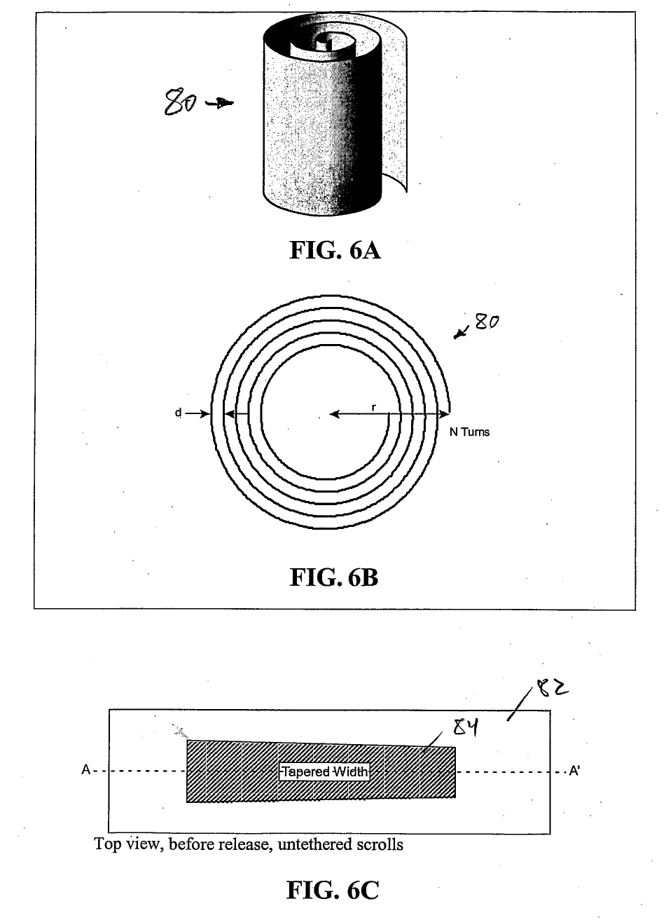

FIG. 6A shows a schematic diagram of a typical Swiss-Roll MRD 80. FIG. 6B shows a cross-sectional view, with radius r, N turns, and capacitive gap d.

The Swiss-Roll resonator is a structure with very high capacitance and inductance per unit length, leading to a resonant structure much smaller than the free space wavelength of light at a given frequency. From Pendry et al., IEEE Trans Microwave Theory and Techniques, 47:2075-2084 (1999), the resonant frequency f₀ is given by:

$${f}_{0} := \frac{1}{2 \cdot π} \sqrt{\frac{{d}_{eff} {c}^{2}}{2 \cdot {π}^{2} \cdot {r}^{3} ( N - 1 )}}$$

where
d_{eff} is the inter-layer gap divided by the average dielectric constant,
c is the speed of light
r is the outer radius of the roll
N is the number of layers

The effective permeability of the Swiss-Roll (derived in Pendry et al., supra) is:

$${μ}_{eff} = 1 - \frac{\frac{π \cdot {r}^{2}}{{a}^{2}}}{1 + \frac{2 \cdot σ \cdot j}{ω \cdot r \cdot {μ}_{0} \cdot ( N - 1 )} - \frac{{d}_{eff} \cdot {c}^{2}}{2 \cdot {π}^{2} \cdot {r}^{3} \cdot ( N - 1 ) \cdot {( ω )}^{2}}}$$

where
a is the diameter of the unit cell occupied by the roll (set equal to 2r here)
σ is the sheet resistivity of the metal layer in the roll, ohms/square
μ₀ is the permeability of free space
j is the square root of −1
ω is the frequency in radians/second
   The equation for effective permeability can be used to find the resonance curve and determine the Q of the resonance. The Swiss-Roll resonator can be fabricated with a Q greater than about 10 (e.g., 25, 50, 75, or 100) at sizes greater than about 25 microns, e.g., 75, 100, 150, or 200 microns. Size, resonant frequency, and Q can be traded off according to the equations above.

A theoretical model of a 4 mm, 101 MHz Swiss-Roll MRD has been constructed in a computer and is shown in FIGS. 6A and 6B. This particular MRD has a large Q of about 3,875, permitting a pulse and ring-down detection scheme, and also includes a nickel layer to induce magnetic field-dependence to resonant frequency.

FIGS. 6C to 6G illustrate a general method of preparing a Swiss-Roll MRD 80. As shown in FIGS. 6C-6E, a rectangular sandwich of two layers of material, having a slightly tapered configuration (i.e., one short end of the rectangle is slightly shorter than the other short end), is deposited onto a sacrificial layer 84, e.g., of SiO₂, or other materials described herein, which is on the surface of a substrate 82, such as a silicon, plastic, ceramic, or glass wafer. The tapered rectangle shape is useful to determine which end of the rectangle is freed first during the undercut etch. FIG. 6D is similar to 6C, except that a hole (anchor region) 81 in the sacrificial layer 84 has been made to anchor the device to the substrate after release. The device of FIG. 6C is not anchored to the substrate and will be free of the substrate after etching away the sacrificial layer.

As best seen in FIG. 6E, the two layers from the top down are a tensile film 88, e.g., of a metal such as aluminum, gold, silver, tungsten, molybdenum, copper, iron, nickel, cobalt, iridium, rhodium, tantalum, or their alloys, and a compressive film 86, e.g., of silicon, Si₃N₄, SiO₂, SiC, Ta₂O₅, or a polymer, such as a polyester (e.g., Mylar®) or polyimide. For example, aluminized Mylar® can be used as the two-layer film. The compressive film 86 may be an insulator to prevent shorting from one loop of the Swiss-Roll to another, or it may be another metal layer, if the coils are loosely rolled so they do not touch.

In FIG. 6D, an anchor region 81 is shown at the wide end of the rectangle. As shown in the side-view of FIG. 6G, this anchor 81 is made simply by etching or otherwise opening a hole in the sacrificial layer 84 before depositing the Swiss-Roll bilayer 86, 88.

As shown in FIG. 6F, devices 80 with no anchor region will be completely free after etching the sacrificial layer 84, and can be placed in suspension by rinsing from the wafer. As shown in FIG. 6G, the device 80 with an anchor region 81 remains attached to the substrate 82 after etching away the sacrificial layer 84. If a liquid etch is used for final release, these freed resonators can be collected from the etch solution by filtration and rinsing.

The tensile film 88 can be put under stress either before or after the device 80 is released from the substrate 82. For example, the tensile layer can be heated, e.g., by Rapid Thermal Anneal (RTA). Stress in the layers can be created by various known methods including differential thermal expansion stress (cooling from the deposition temperature), recrystallization, transition from amorphous state to crystalline state, and chemical or intermetallic reactions.

For example, two metal layers (e.g. Pt and Al) can be co-sputtered to react and form a stressed intermetallic layer upon annealing. Alternatively, an amorphous or micro-crystalline metal layer sputtered onto a low temperature substrate can be annealed at a higher temperature to increase the crystal size, thereby inducing stress. In other embodiments, the state of stress of a sputtered thin film is a function of the sputter pressure. A curled bimorph can be created simply by sputtering the first half of a film at one pressure (e.g., 2 mT of Ar), and the second half at a different pressure (e.g., 8 mT of Ar). Once created, the devices can be coated with polymers, e.g., biocompatible coatings as known and as described herein. Such coatings can change the resonant frequency. For example, coating of a Swiss-Roll device with epoxy can shift the resonant frequency by up to 15 MHz.

If the Swiss-Roll devices are tuned to be exactly on-resonance with the nucleus being imaged, e.g., 127.74 MHz for protons in a 3T field, they distort the BI excitation field when they resonate in response to an excitation field, and hence provide contrast in the setting of protons. Of note, this signal requires no modification to standard pulse sequences and can be acquired rapidly using standard clinical MRI scanners. This phenomenon can also be used when imaging other nuclei by tuning the MRDs to the frequency of the imaged nuclei, as described herein.

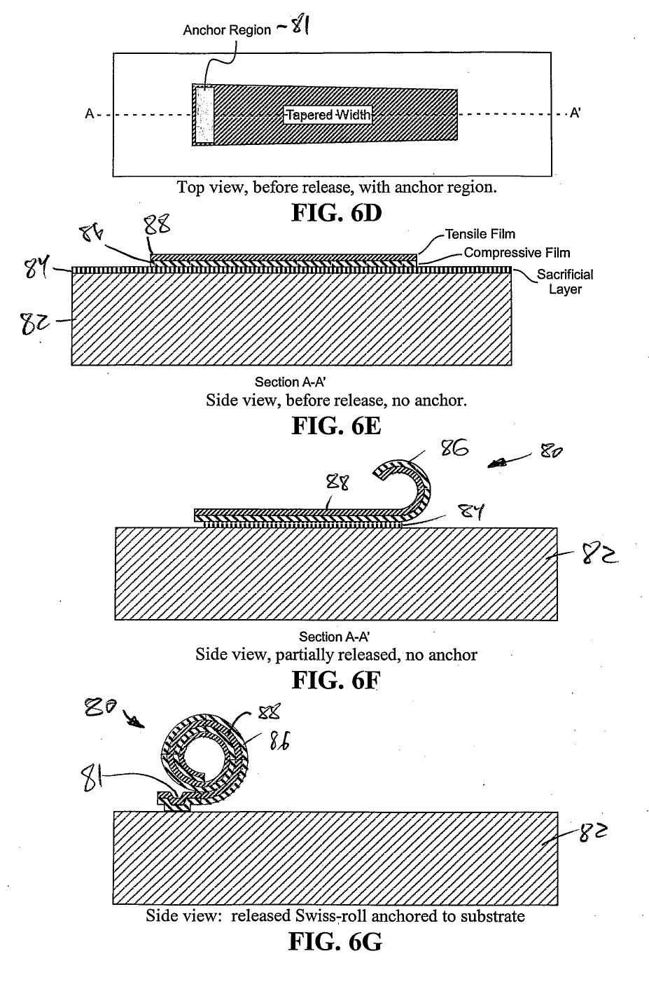

The Swiss-Roll devices can also be tested for various parameters. For example, FIG. 7 shows a graph of the resonance for the theoretical 4 mm diameter device described above. Testing can be carried out for example using a network analyzer, with input waveforms such as swept sine waves or random noise. The electrical signals from the network analyzer are converted to electromagnetic fields using coils or antennas, depending on the frequency range and type of excitation desired. The signal from the MRDs is similarly collected using coils or antennas, which are connected to the input of the network analyzer.

In particular, FIG. 7 shows a sharp resonance in the real part of the permeability defined by the equation for magnetic permeability above. There is a sharp peak at 101.5 MHz and thus, this MRD can be easily detected at this frequency. The high Q indicates that the device can be operated as a Type I device, in which the resonators continue to radiate energy after the excitation stops. Thus, the radiation from the MRD can be detected during the “ring-down” of the oscillator.

Piezoelectric Cantilever Resonator Device with Loop Antenna

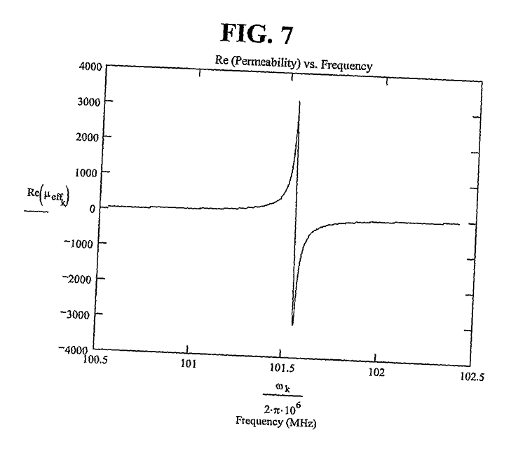

The new MRDs (both Types I and II) can be embodied as a piezoelectric cantilever resonator with a loop antenna, and these resonators can be made using standard MEMS methods. In general, as shown in FIGS. 8A and 8B, this type of MRD 90 includes a chip or substrate 92b, such as a silicon wafer, onto which the cantilever 96 is deposited. The chip or substrate 92 can also be made of, for example, Si₃N₄, SiC, SiO₂, Ta₂O₅, diamond, diamond-like carbon, or any other inert and impermeable insulating solid.

The cantilever 96 can include multiple layers including a structural layer 96a (e.g., Si, polysilicon, Si3N4, or AlN), a first metal layer 96b (e.g., Pt or Au), a piezo film 96c (e.g., PZT, AlN, or ZnO), and a second metal layer (e.g., Al, Au, or Pt). The cantilever 96 is deposited onto the chip 92a using know techniques, e.g., as described above for the cantilever flexural resonator MRD. The precise size, pattern, and location of the cantilever can be established using, for example, photolithographic techniques.

The loop antenna 98 can be made of the same material as the first or second metal, and is connected at one end to the first metal layer 96b of the cantilever and at the other end to the second metal layer 96d. The loop antenna 98 can also be deposited onto chip 92a using standard techniques.

An important aspect of the new cantilever MRDs is to attain a vacuum and a sufficiently high Q at a very small size. This can be achieved by sealing the devices hermetically, preferably in a vacuum, or under low or very low pressure gas. In general, the fewer gas molecules are inside the chamber, the better. Thus, once the cantilever 96 and loop antenna 98 are created, a top cover 92b is sealed onto chip 92a, thus sealing cantilever 96 into cavity 94. The loop antenna 98 can be embedded within or between the cover 92b and chip or substrate 92a.

Other features and materials are as described above for the cantilever flexural resonator MRD.

Planar L-C Resonator Devices

The MRDs described herein can also be manufactured a electromagnetic planar LC-resonators, which can be made using thick/thin film technology. These MRDs include a spiral inductor and a thin-film capacitor. As with other types of MRDs, there is a tradeoff between size and Q, and a 250 micron diameter should provide a value of Q of about 30. A 10 micron diameter device should provide a value of Q of about 1 or less.

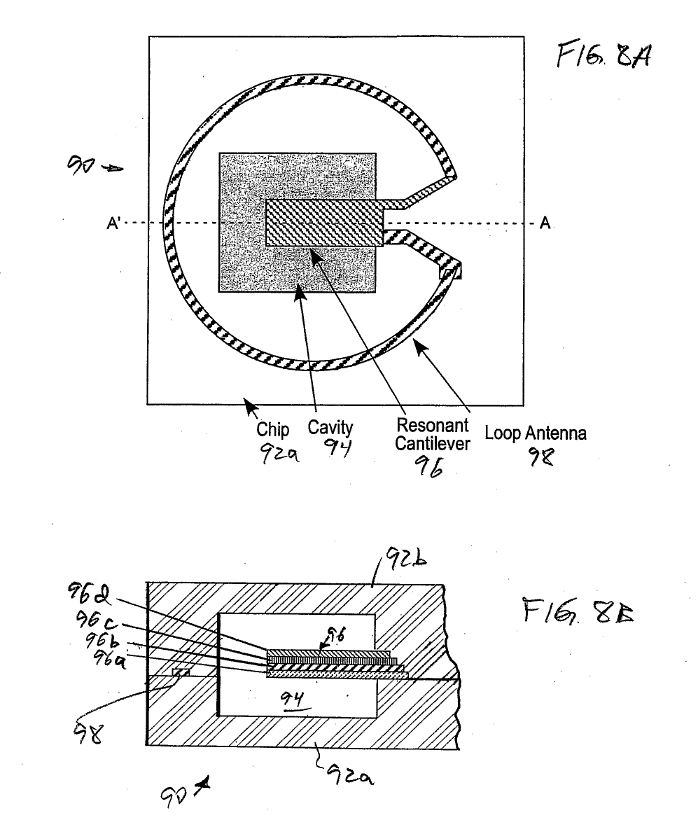

FIG. 9A shows such a planar LC-resonator MRD 100. A spiral conductor electroplated with a conductive metal forms the inductor 102, and thin-film oxide layer forms the capacitor 104. A so-called “air bridge” (or other insulating material bridge) is shown at 106. Contact 108 is formed as an opening by etching through the thin film dielectric. As shown, capacitor 104, which is an under-layer, occupies central turns of the spiral, and the extent of the spiral that is under-laid determines the resonant frequency of the device. The hole 110 in the center allows magnetic flux through the device.

FIGS. 9B to 9G illustrate the process steps in the manufacture of a planar LC-resonator MRD. As shown in FIG. 9B, one starts with a substrate 112, such as glass or silica, and deposit a layer of Ti/Cu/Ta 114, e.g., using the Liftoff technique. This layer is patterned to establish the location of the capacitor.

FIG. 9C shows the next step, in which the surface tantalum in layer 114 is oxidized to form a tantalum oxide layer 116 (e.g., by plasma/thermal oxidation of the Ta film to form Ta₂O₅), or a layer of tantalum oxide (or other high-k thin oxide, e.g., HfO₂, Al₂O₃, or Ta₂O₅) 116 can be deposited, e.g., by ALD (Atomic Layer Deposition). This layer can be about 30 A thick or more.

FIG. 9D shows that an open contact 108 can be etched through the oxide layer 116, and a spacer resist 118 is applied in the location of the eventual air-bridge 106.

Next, as shown in FIG. 9E, a seed layer 120 is sputtered over the entire surface. Seed layer 120 can include an underlying adhesive film (not shown separately) of chrome (e.g., about 500 A thick) and a surface film of copper, nickel, or other metal (e.g., about 2000 A thick). As shown in FIG. 9F, a photoresist 122 is applied to this seed layer 120 and is patterned in the shape of the desired spiral and removed using standard techniques. Either a negative photoresist such as KMPR or SU8 (both from Microchem Corp., Newton, Mass.) or a positive photoresist such as AZ4620 can be used. Once the photoresist is removed, the surface is electroplated with a highly conductive metal layer 124, which forms the spiral inductor coil 102. This coil can be, for example, 20 microns thick (high) and 10 microns wide, and have a spacing of about 5 microns between the turns. The spiral coil can have a high aspect ratio, e.g., 5:1 to 10:1.

The final MRD can be coated with thin polymer (e.g., a photoresist or other coatings as described herein) to protect the MRD from the environment, e.g., water or biological fluids. In addition, laser cut links can be formed in the capacitor to form a trim-able/tunable resonator.

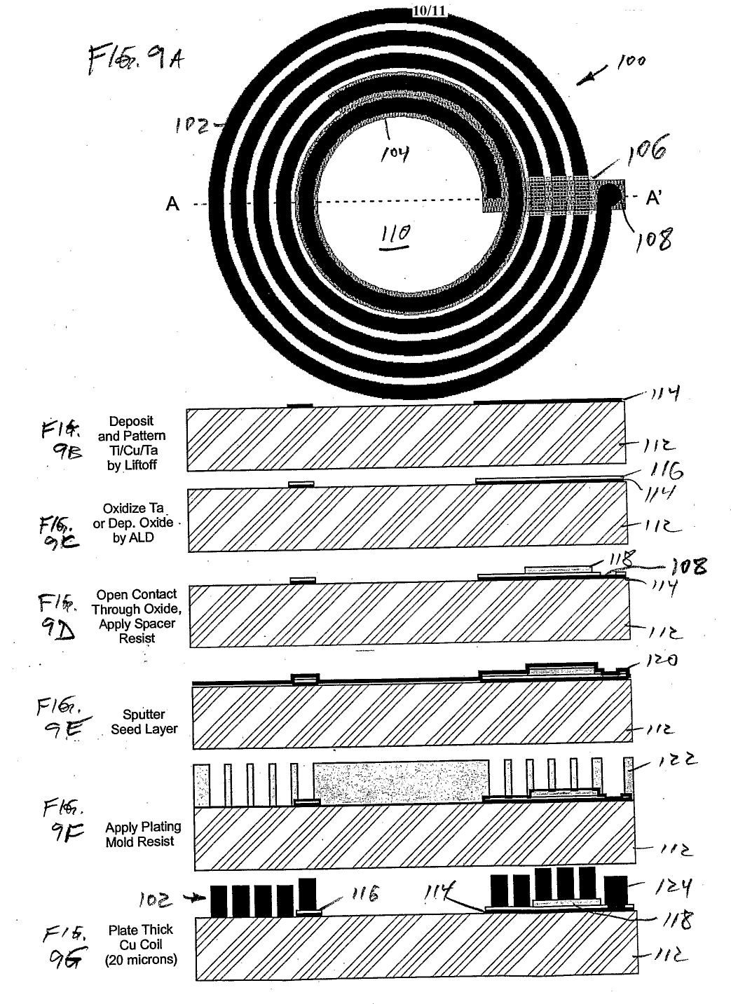

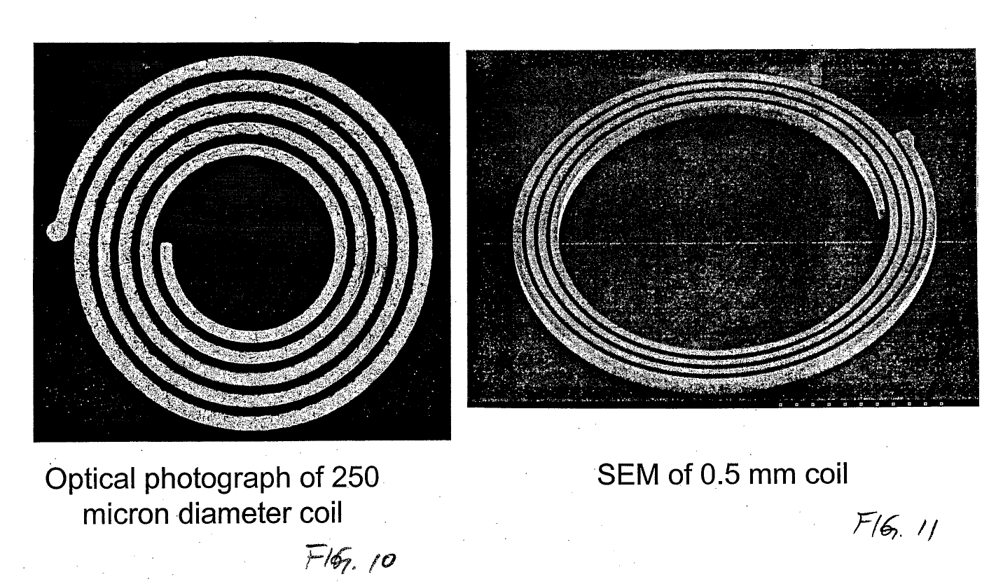

Coil performance (Q) is proportional to how much Cu or Au is deposit to reduce resistance. The larger (thicker) the coil, the lower the resistance and the higher the value of Q. Coils of 250 micron diameter (FIG. 10 shows an optical micrograph), and 0.5 mm diameter have been constructed using these techniques (FIG. 11 shows an SEM). The coil is made from Cu through a KMPR photoresist mold, and is about 20 microns thick.

### Nano-Resonant Devices

Nano-resonant MRDs are each on the nanoscale, i.e., about 500 nanometers or less, e.g., less than 250, 100, 50, 25, 10, or 5 nanometers in overall size. The nano-resonant devices either (i) individually produce a resonant signal, and when acting in concert in a particular target location, the set of nano-resonant devices produces a joint signal of sufficient power to be detected in the same way that a signal from a micro-resonant device is detected, or (ii) individually do not produce a signal, but self-assemble at a target location to form a micro-resonant device that produces a detectable signal. In some embodiments, the nano-resonant devices produce a sufficient signal to be detectable as individual devices.

A nano-resonant device that is 5 nanometers in size can pass through the endothelial walls of blood vessels and can thus pass into tissue cells outside the vasculature. Once congregated or self-assembled at a target location, the set of nano-resonant devices acts like a micro-resonant device.

One type of a nano-resonant device is a metal-coated nanoparticle, such as those made by Biophan. These devices can also be coated with a biocompatible coating for biological and medical uses. In addition, the nano-resonant devices can each include a targeting moiety, that is coupled, e.g., covalently or non-covalently, to the devices, to allow them to home to a particular target location. Examples of such targeting moieties are peptides or other small molecules that bind to specific receptors expressed on cells in normal or disease tissues or organs. Two such types of moieties are described in Frangioni et al. U.S. Pat. No. 6,875,886 (used to target MRDs to prostate cells) and Frangioni et al., U.S. Pat. No. 6,869,593 (used to target MRDs to sites of hydroxyapatite deposition, such as in breast cancer microcalcification or coronary artery calcification). Other biocompatible coatings and targeting moieties are discussed herein.

### Surface Coatings, Targeting, and Handling of MRDs

To render MRDs biocompatible in aqueous buffers, nitride shells can be released from a silicon wafer by etching the silicon using XeF₂, TMAH, KOH, or any of the well-known Si etches. The micro-encapsulated resonators can be recovered from the etchant by filtration and rinsed to remove the etch. At this point they can be coated chemically, or by LPCVD (Low-Pressure Chemical Vapor Deposition). For example a coating of a bio-inert layer, for example, parylene or polyethylene glycol (PEG) can be added at this point. Parylene coatings have demonstrated excellent biocompatibility, hemocompatibility, and non-cytotoxicity in a wide range of implantable medical applications, including catheters, cardiac assist devices, guide wires and needles and epidural probes. Parylene coatings are typically applied in a vapor phase and can therefore provide a precisely controlled layer that can be one molecule thick and very smooth.

Derivatized PEG, especially asymmetric carboxylated PEG, is also an attractive coating because endocytosis-promoting molecules (see below) can be conjugated covalently through straightforward N-hydroxysuccinimide (NHS) ester chemistry utilizing N-3-dimethylaminopropyl1-N-ethylcarbodiimide (EDC) and sulfo-NHS (both from Pierce).

In other aspects, the MRDs can be coated with chemically modified carbon nano-wires, to provide for a stable, inert, and biocompatible outer surface. The hydrophilic outer coatings can also include bioactive molecules that are released into the environment, e.g., into a cell, over time. This molecular release can be passive and occur over time as the coating is degraded and absorbed by the cell, or active, e.g., triggered by a change in the environment, e.g., temperature, pH, or light. The coating can also be designed to change from hydrophilic to hydrophobic as a result of a change in a property of the device or the environment, e.g., an electrical property of the environment or the device. This last embodiment has utility as a method for ejecting the new MRDs from within cells so the MRDs can be cleared from the body.

The new MRDs can be designed to target or “home” to specific molecular ligands/targets in a particular environment, such as the body of a human or animal subject. For example, many ligand-receptor pairs are known in biology, and one of the pair can be attached to the surface of an MRD to enable it to home to the binding partner. These ligands/binding partner moieties can be polypeptides, carbohydrates, or organic or inorganic small molecules, e.g., of about 1000 Da or smaller, e.g., 750, 500, 300 Da or smaller. See, e.g., Frangioni et al. U.S. Pat. No. 6,875,886 (moieties used to target MRDs to prostate cells) and Frangioni et al., U.S. Pat. No. 6,869,593 (moieties used to target MRDs to sites of hydroxyapatite deposition, such as in breast cancer microcalcification or coronary artery calcification). See also, Brown, “New Approaches for Cell-Specific Targeting,” Curr. Op. Chem. Biol., 4:16-21 (2000), which describes peptides that recognize specific cell types. In specific embodiments, serotonin-linked MRDs can target cells that express serotonin receptors, transferrin-linked MRDs can target cells that express transferrin receptors, and Low Density Lipoprotein (LDL)-linked MRDs can target cells that express LDL receptors (apolipoprotein B-100 receptor).

Alternatively, antibodies to a specific target can be prepared using standard techniques and linked to the surface of the new MRDs.

If the MRDs are designed to be engulfed by cells, e.g., for use in vivo, they can be coated with moieties that induce or enhance receptor-mediated endocytosis. The ideal endocytosis efficiency would be 100% at a MRD to cell ratio of 1.

For example, the MRDs can be coated, either covalently or non-covalently, with peptides of about 3 to 10, e.g., 8 or 9, amino acids in length. One type of such peptide contains the RGD-consensus sequence. Such peptides bind avidly to cell surface integrins and promote endocytosis. Various polypeptides that can be used to coat MRDs to induce endocytosis include transferrin, low density lipoprotein (LDL), transcobalamin, IgE, polymeric IgA, and IgG. Various hormones can be linked to the MRDs to induce endocytosis including insulin, epidermal growth factor, growth hormone, thyroid stimulating hormone, nerve growth factor, calcitonin, glucagon, prolactin, luteinizing hormone, thyroid hormone, platelet derived growth factor, interferon, and catecholamines.

In other embodiments, the endocytosis promoting molecule is a large molecule, with more cell surface interactions, such as fibronectin. It has been shown that fibronectin promotes the efficient endocytosis of microspheres up to 10 μm in diameter.

Biocompatible MRDs are sterilized prior to in vitro and in vivo characterization by precipitation in absolute ethanol, collection by centrifugation at 100×g, and drying in a negative-pressure tissue culture hood.

The coating materials selected for this application must meet extraordinary requirements for uniformity and mechanical properties, thus another useful material for producing a biocompatible coating is ultrananocrystalline diamond (UNCD). These new materials have controlled grain sizes in the 2-5 nm range, adhere well to MEMS structures, and have the potential for providing hermetic sealing without interference in signal transmission or mechanical properties of the MRDs.

Because of their small size, the new MRDs are handled in unique ways. For example, a combination of suspension in fluid and sieving can be used to easily and efficiently handle the MRDs. For example, passage of coated MRDs through a No. 450 (12 μm diameter) sieve cloth (Metalweave, Inc., Amesbury, Mass.) will remove any devices that have clumped or do not meet size specifications. Devices can then be collected on a No. 635 (8 μm diameter) sieve cloth, washed or chemically modified, then concentrated by low speed (100×g) centrifugation.

### Tracking and Imaging MRDs

Although MRI scanners can be used very effectively to track and image Type I MRDs, they are not required for 3-D localization of type II MRDs, because the distinct emission signal can be detected using focused send/receive antenna pairs. Hardware to detect MRDs in three-dimensional space functions in a manner analogous to the satellite GPS system surrounding the earth. Such new hardware can be used to detect MRDs in any location or environment, with lightweight and rugged equipment. In general, the new MRDs can be designed to be useful in a wide range of wavelengths from about 10 KHz to about 100 GHz depending on their use. As discussed above, some of the new MRDs can be used in the THz range of frequencies.

A simple tracking device consists of a single send/receive antenna that is focused to a precise point in 3-D space. To create an image of a large object, such as a human body, the antenna would be scanned in three dimensions, e.g., in a circular, up/down, and in/out, thus probing the entire 3-D space occupied by the large object. Another more complex device consists of a ring of antennae, or multiple rings of different diameter, that are simply scanned in one direction, e.g., up and down, to reconstruct a 3-D location of any MRDs. Another device includes a large, but finite, number of antennae that could reconstruct the position of MRDs in 3-D space without moving parts.

These known devices will work in their standard way to detect, track, and image the new MRDs. One administers a number of the new MRDs, e.g., by systemic injection, allows adequate time for the MRDs to “home” to a target site, and then operate the device using standard techniques. Of course, adjuvant imaging techniques, such as computed tomography (CT) or conventional proton MRI can be used together with the tracking and imaging of the new MRDs to correct MRD signals, e.g., for attenuation by thick or dense bodily tissue.

In certain embodiments, the Type I MRDs can be tuned to the same frequency as the nuclei being imaged, and can then be imaged based on the contrast they create by distorting the excitation field in their vicinity. For example, an MRD tuned to resonate at 127.74 MHz (in a 3T excitation field) can be detected by standard clinical MRI of protons by the distortion in the field, which has the appearance, for example, in a spin-echo MRI image, of ripples from a pebble dropped in a pond. In the same way, the distortion looks like waves that emanate from the location of the MRD in the image. In other words, the MRD itself is not seen in the image, just the wave pattern around the location of the MRD.

### Methods of Use

The new MRDs have many uses, both in the medical and biological fields, and in industrial and environmental fields.

For example, in medicine, stem cells hold tremendous promise for the treatment of human disease, and are already being utilized in clinical trials. For many diseases, such as diabetes, there is a distinct possibility that single stem cells scattered diffusely throughout the body might be effective therapeutics. However, there is currently no available method to track single, or even small numbers of stem cells as they traverse the body. Without the ability to follow the migration of stem cells and to quantify cell number in any anatomic location, it will be virtually impossible to assess the contribution of stem cells to clinical outcomes. All presently available imaging modalities, including nuclear medicine (SPECT and PET scanning), computed tomography, MRI, and ultrasound, are between seven and nine orders of magnitude less sensitive than what is needed for single stem cell tracking.

The new MRDs solve the problem of single stem cell tracking and can also be applied to a variety of additional problems in medicine and beyond, which require event tracking in 3-D space. For cancer research, MRDs can be used to track single metastatic cells as they home to different organs or tissues. For diabetes research, MRDs can be used to track single CD8+ lymphocytes as they invade pancreatic islets.

MRDs can also be modified to incorporate intracellular sensors for pH, pCa, nucleic acid hybridization, specific chemicals, etc. that would change MRD emission characteristics in response to the detected event. MRDs can thus provide a mechanism to measure events at the single cell level in vivo. For example, this can be accomplished by modifying one side of the Swiss-Roll structure so that it can chemically adsorb the chemical to be sensed. This adsorption changes the surface energy and hence the surface stress on one side of the scroll, which changes the radius of curvature and hence the resonant frequency of the structure. This change in the resonant frequency in the presence of the specific chemical to be detected can be measured.

In addition, MRDs can absorb energy at levels above those required for the MRD to produce an emission signal. This energy-absorbing feature of MRDs can be exploited to synchronously kill MRD-containing cells anywhere in the body. For example, materials can be chosen such that power applied above a certain threshold results in heating of the MRD to a temperature above 37° C., which can cause direct cell killing. In specific examples, image-guided, single-cell killing could be used to destroy stem cells after they have restored a particular bodily function or to investigate how dead cells are cleared by the reticuloendothelial system.

Beyond medicine on a cellular level, MRDs can be considered “invisible” radiofrequency identification (RFID) tags. As such, they can be used to track instruments during robotic surgery, catheters during invasive procedures, sponges and other small objects in the operating room.

Outside of medicine and biology, the new MRDs can be used to track objects or materials on assembly lines or in process lines. The MRDs can even be used to track individuals during covert operations, e.g., by being implanted under the skin or merely attached to articles of clothing.

### EXAMPLES

The following examples are illustrative and not limiting.

### Example 1

### In Vitro Characterization

Coated MRDs are characterized by measuring their resonant frequency, Q, and signal using a network analyzer. These measurements are conducted systematically in air versus water, and at temperatures ranging from 4° C. to 60° C., to determine how environment affects MRD performance. Based on these initial results, custom pulse sequences are written for a GE 3T MRI scanner to first detect, and then localize MRDs in 3-D space.

In vitro cellular characterization is performed on 19.2 μm diameter (3.7 pL) PC-3 human prostate cancer cells. An MRD having an overall diameter of about 10 μm and a volume of about 528 fL will occupy approximately 14% of PC-3 cell volume. The efficiency of MRD endocytosis into cells is optimized using the following procedure. First, MRDs without endocytosis-promoting molecules are added to the cell culture medium of PC-3 cells in exponential growth phase, and a confluence of 50%, in 24-well plates. The number of MRDs per cell is tested at ratios of 1, 10, and 100. After incubation for 1, 4, and 16 hours at 37° C., cells are washed 3× with cell culture medium, viewed using phase contrast microscopy, and MRDs per cell counted. This measurement serves as the baseline for all attempts to improve endocytosis efficiency. To do so, MRDs are coated, either covalently or non-covalently, with endocytosis-promoting peptides of 8 or 9 amino acids in length that include an RGD-consensus sequence. Such peptides bind avidly to cell surface integrins and promote endocytosis.

Since it is unclear if covalent conjugation of these peptides is necessary for efficient endocytosis, they are tested after simple adsorption to MRDs followed by a single wash using a No. 635 sieve cloth versus covalent conjugation of the peptide's α-amine using a straightforward N-hydroxysuccinimide (NHS) ester chemistry utilizing N-3-dimethylaminopropyl1-N-ethylcarbodiimide (EDC) and sulfo-NHS (both from Pierce).

Cells loaded with 1 MRD per cell are then serially diluted into 500 μL Eppendorf tubes, and imaged using a 3T MRI scanner. The goal of this exercise is to determine the limit of cellular detection as a function of voxel size, and to optimize MRI pulse sequences to improve the signal to background ratio. Conventional proton imaging is conducted in parallel so that the MRD signal and anatomy can be superimposed.

PC-3 cells are loaded with 1 MRD per cell and also collected by trypsin/EDTA treatment and low-speed centrifugation. The cells are then subjected to in vitro toxicity assays including cell proliferation (Coulter counting and bromodeoxyuridine incorporation), cell cycle (flow cytometry after DAPI staining), and apoptosis (TUNEL staining). MRDs that exhibit unexpected toxicity in these assays are systematically analyzed to determine if size, biocompatible coating, metal leaching, or a combination thereof are the cause of the toxicity.

All of the above cellular experiments are repeated on pig mesenchymal stem cells (MSCs). Pig MSCs are only 13.5 μm in diameter (1.3 pL), and a single 10 μm MRD will occupy a larger fraction of cell volume (≈40%). These tests will determine whether stem cells tolerate MRDs as well as PC-3 cells do, and how MRD size affects MSC proliferation, mobility, and differentiation. Since MRD volume scales with the 3^{rd} power of radius, even small changes in diameter will result in profound changes in volume. For example, reducing MRD size from 10 μm diameter to 7 μm diameter will result in a volume change from 528 μL to 180 fL. This would reduce MRD volume as a function of cell volume from 40% to 14% and 14% to 5%, in pig MSCs and PC-3 cells, respectively.

### Example 2

### In Vivo Characterization

PC-3 cells loaded with 1 MRD per cell are co-incubated with the near-infrared (NIR) fluorophore IR-786 as described previously (Nakayama et al., Molecular Inaging, 2:37-49, 2003). IR-786 concentrates to over 1 mM in the intracellular membranes of cells and permits even single cells to be located in vivo by surgical exploration when used with a custom intraoperative imaging system (Nakayama et al., Molecular Imaging, 1:365-377, 2002). PC-3 cells loaded with MRD/IR-786 are injected subcutaneously on the backs of SKH-1 hairless mice (Charles River Labs) at a total cell number of 10⁶, 10⁵, 10⁴, 10³, 10², and 10¹ cells per injection site.

Animals are imaged immediately using 3T MRI and NIR fluorescence. Mouse proton MRI is performed as described previously in Zaheer et al., Nat. Biotechnol., 19:1148-1154 (2001). Mice are anesthetized using 60 mg/kg pentobarbital injected intraperitoneally, are then placed in a custom low-pass birdcage coil (10 cm length, 6 cm diameter), and imaged with a 3T whole-body scanner (GE Medical Systems, Waukesha, Wis.). Images are acquired with an 8 cm FOV using a 3-D fast gradient echo sequence. Other parameters include a 256×256 pixel matrix size, slice thickness of 0.7 mm, TE=2.6 ms, TR=10.2 ms, and flip angle=15°.

MRD MRI imaging is performed using standard protocols optimized based on the characterization of the MRDs described in Example 1. NIR fluorescence imaging is also performed using a custom NIR diode array, custom excitation and emission filters, and an Orca-AG camera exposure time of 1 second (see, e.g., DeGrand et al., Technol. Cancer Res. Treat., 2:553-562 (2003). The NIR fluorescence imaging system simultaneously displays color video along NIR fluorescence; thus, it can co-register MRI and optical images, unequivocally, and therefore ensure that any signal seen by MRI is actually being generated by MRD-loaded cells.

We have previously calculated that for a 13.5 μm diameter pig mesenchymal stem cell, a metal object in the cytoplasm≧6 μm in diameter would generate sufficient CT contrast to be seen at the single voxel level. The GE eXplore RS micro-CT is capable of 25 μm voxels, which suggests that as few as 4 MRD-loaded cells (i.e., filling one voxel) can be tracked anywhere in the animal. Hence, micro-CT will provide independent verification of stem cell/MRD location, and can be co-registered with MRI using sub-millimeter technetium-99m calibration/co-registration sources previously described in English et al., Mol. Imag. Biol., 4:380-384 (2002).

These calibration sources contain a high atomic number molecule such as iodine in molar concentrations, and can also be loaded simultaneously with anionic derivatives of gadolinium-loaded DOTA to generate contrast by MRI

### Other Embodiments

A number of embodiments of the invention have been described. Nevertheless, it will be understood that various modifications may be made without departing from the spirit and scope of the invention. Accordingly, other embodiments are within the scope of the following claims.

1. A monolithic, micro-resonant device comprising
an antenna component that receives an excitation signal and transmits an emission signal; and
a resonator component that receives an excitation signal and generates a corresponding emission signal; and, optionally
an outer coating that envelopes the device and isolates the device from its environment;
wherein the device has an overall diameter of less than about 1000 microns and a Q value of greater than 5; and wherein the emission signal comprises (i) a resonant frequency of the device emitted at a delayed time compared to the excitation signal, (ii) a frequency different than the excitation signal; (iii) a signal at a different polarization than the excitation signal, or (iv) a resonant frequency of the device, which upon excitation by an applied excitation field distorts the applied excitation field.

2. The device of claim 1, wherein the overall diameter is less than or equal to 10 microns.

3. The device of claim 1, wherein the antenna component and the resonator component are the same component.

4. The device of claim 1, wherein the coating is present and comprises a biocompatible coating.

5. (canceled)

6. (canceled)

7. (canceled)

8. The device of claim 1, wherein the device further comprises an endocytosis-promoting molecule linked to the coating.

9. The device of claim 8, wherein the endocytosis-promoting molecule comprises a peptide comprising an amino acid sequence RGD, a transferrin molecule, a fibronectin molecule, an LDL cholesterol molecule, or an apoliprotein B-100 molecule.

10. The device of claim 1, wherein the resonant frequency comprises a frequency not present in a subject into which the device is to be implanted or a frequency present in the subject at a background level.

11. The micro-resonant device of claim 1, wherein the device has a diameter of less than 10 microns and a Q value greater than 100, and wherein the resonant frequency is proportional to an applied magnetic field.

12. (canceled)

13. The device of claim 11, wherein the resonator comprises a magnetic metal or alloy to induce magnetic field dependence to the resonant frequency.

14. (canceled)

15. (canceled)

16. (canceled)

17. (canceled)

18. The device of claim 1, wherein the Q value is greater than 200.

19. The device of claim 1, wherein the coating is present and comprises one or more targeting agents.

20. A micro-resonant device comprising:
a cylindrical or prismatic length extender bar comprising a transducer material and having a length of less than about 100 microns and a diameter of less than about 100 microns; and optionally
an outer coating that envelopes the device and isolates the device from its environment;
wherein the device resonates at a resonant frequency of greater than about 50 MHz after receiving an excitation signal at the resonant frequency.

21. The device of claim 20, wherein the transducer material comprises a piezoelectric or a magnetostrictive material.

22. The device of claim 20, wherein the outer coating is present and comprises an outer layer comprising a hydrophilic material encompassing the device; and an inner layer comprising a hydrophobic material located between the outer layer and the bar.

23. The device of claim 20, wherein the device has a Q value greater than 5.

24. The device of claim 20, wherein the transducer material is zinc oxide, aluminum nitride, a nickel alloy, or a magnetostrictive ferrite containing Fe, Ni, or Co.

25. (canceled)

26. The device of claim 22, wherein the inner layer comprises a porous material of low density, or a block-copolymer from which one of the co-polymers has been removed.

27. The device of claim 20, wherein the resonant frequency is greater than about 400 MHz.

28. The device of claim 20, wherein the resonant frequency is greater than about 2 GHz.

29. The device of claim 20, wherein the length is about 16 microns and the transducer material comprises zinc oxide.

30. The device of claim 20, wherein the length is about 12 microns, and the transducer material comprises a nickel alloy.

31. A micro-resonant device comprising:
a hermetically-sealed housing comprising walls forming an internal chamber;
a cantilever arranged within the internal chamber and comprising a free end and a fixed end connected to a wall of the housing; and
an electrode arranged within the internal chamber spaced from the cantilever or a loop antenna having two ends, wherein the two ends both contact the cantilever;
wherein the overall size of the device is no larger than about 1000 microns.

32. The device of claim 31, further comprising a biocompatible coating on an external surface of the housing.

33. The device of claim 31, wherein the chamber is substantially free of gas molecules.

34. The device of claim 31, wherein the cantilever and the electrode each comprise silicon and the housing comprises silicon nitride.

35. The device of claim 31, wherein the cantilever and electrode comprise the same material.

36. The device of claim 31, wherein the biocompatible coating comprises a parylene, polyethylene glycol, carbon, sugar, carbohydrate, hydrophilic peptide, amphilic peptide, surfactant, or an amphilic polymer.

37. The device of claim 31, wherein the cantilever and the electrode comprise materials with different electron work functions.

38. (canceled)

39. The device of claim 31, wherein the device has an overall size of less than about 10 microns.

40. The device of claim 31, wherein the cantilever comprises a magnetic metal or alloy to induce magnetic field dependence to the resonant frequency.

41. A micro-resonant device comprising
a sandwich of at least two layers rolled into a cylinder, wherein a first layer comprises a conductor and a second layer comprises an insulator;
wherein the device has an overall diameter of less than 5 mm and a Q value of greater than 5; and wherein when exposed to an excitation signal at a resonant frequency of the device, the device generates an emission signal comprising the resonant frequency for a time after the excitation signal has ended.

42. The device of claim 41, further comprising a third layer comprising a magnetic layer.

43. The device of claim 42, wherein the magnetic layer comprises iron, nickel, cobalt, or alloys thereof.

44. The device of claim 41, further comprising an outer coating that envelopes the device and isolates the device from its environment.

45. (canceled)

46. (canceled)

47. (canceled)

48. (canceled)

49. The device of claim 41, wherein the overall size is less than about 1 mm, and the Q value is greater than 30.

50. The device of claim 41, further comprises a targeting agent linked to the device.

51. A micro-resonant device comprising
a planar spiral comprising at least two layers, wherein a first layer comprises an inductor and a second layer comprises a thin-film capacitor;
wherein the device has an overall diameter of less than 500 microns and a Q value of greater than 5; and wherein when exposed to an excitation signal at a resonant frequency of the device, the device generates an emission signal comprising the resonant frequency.

52. The device of claim 51, wherein the inductor comprises copper, the overall diameter is less than 250 microns, and the Q value is at least 25.

53. A method of locating a micro-resonant device, the method comprising
(a) obtaining one or more micro-resonant devices (MRD) of claim 1 and distributing them in a target area;
(b) generating an excitation signal in at least a portion of the target area in which the one or more devices might be located;
(c) receiving an emission signal from the one or more devices, if any, in the portion of the target area; and
(d) processing the emission signal to determine the location of the one or more devices.

54. The method of claim 53, further comprising imaging the device by processing the emission signal and generating an image from the processed emission signal.

55. The method of claim 53, wherein the device has an overall diameter of about 10 microns or less, and is located within a cell, thereby enabling the cell to be located within the area.

56. The method of claim 53, wherein the emission signal is a resonant frequency of the device, wherein the device further comprises a magnetic material to induce magnetic field dependence to the resonant frequency, and wherein the method further comprises exposing the target area to a magnetic field.

57. The method of claim 53, wherein the target area is within an animal or human body.

58. The method of claim 53, wherein the emission signal comprises a frequency of at least 100 MHz.

59. (canceled)

60. The method of claim 53, wherein the MRD is attached to an object, and the method is used to track the object within a target area.

61. (canceled)

62. The method of claim 53, wherein the MRD is attached to or carried within a human or animal body, and the method is used to track the body in a target area.

63. The method of claim 53, wherein the MRD comprises a ligand that specifically binds to a target moiety and further wherein binding of the ligand to the target moiety induces a change in the frequency of the emission signal of the MRD, and the method is used to sense a change in the environment of the target area.

64. (canceled)
